(19) United States
(12) Patent Application Publication
(10) Pub. No.: US 2026/0188629 A1
(43) Pub. Date: Jul. 2, 2026

(54) SUBSTRATE PROCESSING APPARATUS INCLUDING ELECTROMAGNET UNIT

(71) Applicant: SEMES CO., LTD., Cheonan-sii (KR)

(72) Inventors: Bong Ju KIM, Cheonan-si (KR); Seung Pyo LEE, Cheonan-si (KR); Ji Hoon LEE, Cheonan-si (KR); Yong Jun SEO, Cheonan-si (KR); Young Sik BANG, Cheonan-si (KR); Ik Ho LEE, Cheonan-si (KR)

(73) Assignee: SEMES CO., LTD., Cheonan-si (KR)

(21) Appl. No.: 19/431,801

(22) Filed: Dec. 23, 2025

(30) Foreign Application Priority Data
Dec. 31, 2024 (KR) 10-2024-0202595

(51) Int. Cl. H01J 37/32; H10P 72/00

(52) U.S. Cl. CPC H01J 37/32669; H01J 37/3244; H10P 72/0604; H01J 2237/152; H01J 2237/334

(57) ABSTRACT

Disclosed is a substrate processing apparatus that controls plasma density distribution using an electromagnet unit. The substrate processing apparatus controls magnetic field intensity and distribution using a variable core, controls a magnetic field formed on a substrate during substrate processing operation based on a magnetic field profile constructed in advance through a first magnetic field measurement sensor and a second magnetic field measurement sensor, and diagnoses the state of the electromagnet unit.

### CROSS-REFERENCE TO THE RELATED APPLICATION

The present application claims priority to and the benefit of Korean Patent Application No. 10-2024-0202595, filed on Dec. 31, 2025, in the Korean Intellectual Property Office, the entire disclosure of which is incorporated herein by reference.

### BACKGROUND

### 1. Field

The present disclosure relates to a substrate processing apparatus including an electromagnet unit, and more particularly, to a substrate processing apparatus including an electromagnet unit capable of precisely controlling a magnetic field in real time.

### 2. Description of the Related Art

Substrate processing apparatuses using plasma are employed to manufacture semiconductor devices. Plasma is generally used in a deposition process for forming a predetermined film on a substrate such as a semiconductor wafer and in an etching process for forming a predetermined pattern in the film formed on the substrate.

A plasma processing apparatus may employ an electromagnet in order to control plasma density distribution in a chamber. The electromagnet includes a coil and is primarily disposed outside the chamber in which the substrate is accommodated. When current flows through the coil, a magnetic field is formed inside the chamber. The density distribution of the plasma formed in the chamber may be controlled by adjusting the intensity or distribution of the magnetic field.

For example, a technique in which a plurality of annular electromagnets is disposed above a chamber in order to control a magnetic field in the chamber may be proposed. However, in such a structure, it may be difficult to precisely control the distribution of the magnetic field formed in a substrate processing region.

In addition, a technique in which a magnetic field measurement sensor is provided within a magnetic field generating range of an electromagnet in order to precisely and accurately measure the intensity of a magnetic field formed on a substrate may be proposed. However, because the magnetic field measurement sensor is not allowed to be directly disposed in a process region in which plasma reaction is performed, magnetic field information based on the substrate may not be collected while an actual process is carried out.

Conventionally, magnetic field intensity is cumulatively collected through output evaluation of specifications of an actual electromagnet and is combined with nonlinear numerical analysis data based on simulation, so that the magnetic field in a substrate region is estimated from the magnitude of current supplied to the electromagnet, and an appropriate current control value is determined. However, the magnetic field intensity calculated in the simulation may not perfectly reflect the influence of actual environmental factors, and errors may occur due to durability issues during operation, resulting in degradation in process yield.

Therefore, there is a need for control technology capable of precisely monitoring magnetic field distribution on a substrate formed by an electromagnet and performing periodic calibration.

### SUMMARY

The present disclosure is directed to addressing the problems of the related art described above, and to providing technology capable of precisely controlling a magnetic field during a substrate processing operation.

Furthermore, the present disclosure is directed to providing technology capable of reducing an error between the distribution and intensity of a target magnetic field intended to be formed in a substrate processing region and the distribution and intensity of an actually output magnetic field.

In addition, the present disclosure is directed to providing technology capable of identifying whether an electromagnet unit (e.g., an electromagnet unit including a coil current circuit or a magnetic field sensor module) normally operates during a substrate processing operation, thereby determining in real time whether maintenance is required.

The objects to be accomplished by the disclosure are not limited to the above-mentioned objects, and other objects and advantages not mentioned herein may be understood from the following description.

A substrate processing apparatus according to the present disclosure, in which plasma processing is performed on a substrate, includes a chamber having a processing space defined therein to process the substrate, a substrate support unit configured to support and fix the substrate disposed thereon, a gas supply unit including a showerhead configured to supply gas to the processing space, and an electromagnet unit configured to generate a magnetic field above the chamber, wherein the electromagnet unit includes an electromagnet power supply configured to supply power, a coil module configured to receive power from the electromagnet power supply to generate a magnetic field in the processing space, and a variable core configured to be magnetized by the magnetic field generated by the coil module to generate a magnetic field, and the variable core is replaced or is adjusted in position to control the magnetic field formed in the processing space.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing the configuration of a substrate processing apparatus according to an embodiment of the present disclosure;

FIGS. 2A to 2D are top views of various embodiments of a coil module and a variable core according to the present disclosure;

FIG. 3 is a longitudinal-sectional view of the coil module and the variable core according to the present disclosure, taken along line A-A in FIG. 2A;

FIG. 4 is a view showing the configuration of a substrate processing apparatus including a magnetic field measurement module according to the present disclosure;

FIG. 5 is a view schematically showing a configuration for measuring a magnetic field in the substrate processing apparatus shown in FIG. 4;

FIG. 6 is a window map representing control parameters that are adjusted when a magnetic field is measured as shown in FIG. 5;

FIGS. 7A to 7D are comparison graphs showing variations in magnetic field intensity depending on the presence or absence of the variable core; and

FIG. 8 is a block diagram showing some components for adjusting a magnetic field formed in a processing space in the substrate processing apparatus shown in FIG. 4.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, a substrate processing apparatus configured to precisely adjust a magnetic field distribution during a substrate processing operation in which plasma distribution is adjusted using a magnetic field will be described. The substrate processing apparatus includes a chamber providing a processing space in which a substrate is processed. The substrate processing apparatus includes a gas supply unit and a plasma generating unit, thereby supplying plasma generated by excitation of gas to the processing space. The substrate processing apparatus includes an electromagnet unit provided above the chamber in order to adjust distribution of the plasma supplied to the processing space. In particular, a coil module of the electromagnet unit may receive power from an electromagnet power supply and may generate a magnetic field in the processing space, thereby adjusting the plasma distribution.

In addition, the electromagnet unit of the present disclosure includes a basic coil structure having a function of applying current to generate a magnetic field and a variable core structure that is operable separately. In particular, the variable core may be configured such that the magnetic field generated from the coil module is concentrated thereon. Furthermore, the variable core may vary the intensity of the generated magnetic field. That is, the variable core may control distribution of plasma formed in the processing space by adjusting the characteristics of the generated magnetic field. For example, the magnetic field distribution may be varied as the mounting height of the variable core is adjusted. Alternatively, the variable core may be provided and replaced in any of cartridge forms having different materials or shapes such as lengths, widths, or inner diameters, thereby varying the distribution of the magnetic field formed in the processing space.

In another example, the substrate processing apparatus may include a magnetic field measurement module to simultaneously or independently measure the intensity of the magnetic field formed in a space adjacent to the coil module and the intensity of the magnetic field formed in the plasma processing space. The magnetic field measurement module measures, before the substrate processing operation is performed, the magnetic field intensity using a first magnetic field measurement sensor mounted in a first region adjacent to the coil module and a second magnetic field measurement sensor disposed in a second region above an electrostatic chuck on which a substrate is supported. That is, the substrate processing apparatus may identify a correlation of magnetic field intensity between the two regions so that the intensity of the magnetic field formed in the second region is estimated from the magnetic field intensity measured in the first region.

Furthermore, after the substrate processing operation is started, the magnetic field measurement module measures the intensity of the magnetic field formed in the first region. Subsequently, the measured value is converted into a corresponding control parameter (e.g., the magnitude of current supplied to the coil module or the material or shape of the variable core) based on a previously obtained magnetic field correlation. By comparing the converted control parameter with a set control parameter, whether a magnetic field is normally formed in the second region may be determined.

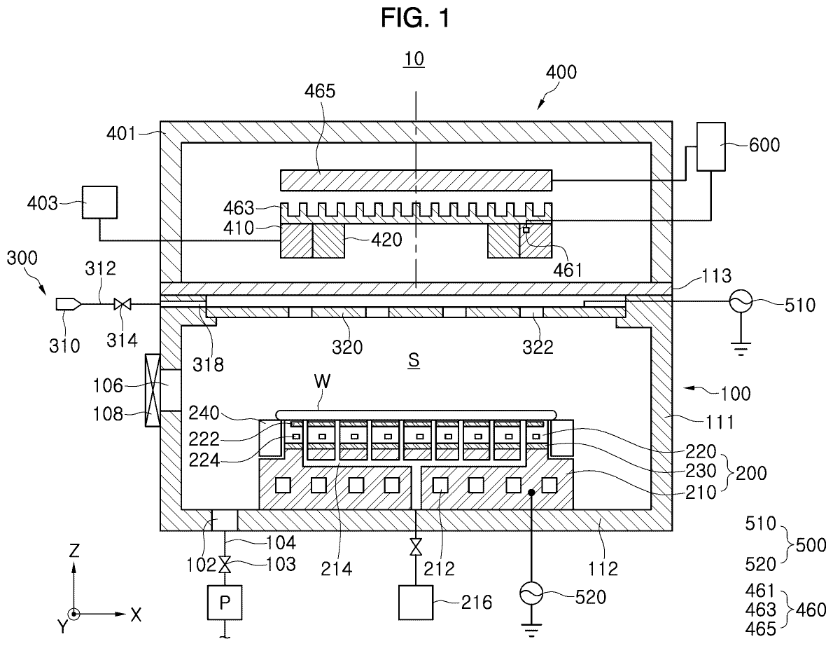

Hereinafter, the substrate processing apparatus of the present disclosure will be described in detail with reference to FIGS. 1 to 8.

FIG. 1 is a view showing the configuration of a substrate processing apparatus according to an embodiment of the present disclosure. Referring to FIG. 1, the substrate processing apparatus 10 according to an embodiment of the present disclosure includes a chamber 100, a substrate support unit 200, a gas supply unit 300, an electromagnet unit 400, a plasma generating unit 500, and a controller 600.

The chamber 100 has a processing space S defined therein, and substrate processing operation is performed in the processing space S. The processing space S in the chamber 100 is defined by a chamber sidewall 111, a chamber bottom 112, and a chamber cover 113. The chamber 100 may be formed of a metal such as aluminum. For example, the substrate processing operation may be a plasma etching process. The substrate processing operation may be performed under a reduced pressure atmosphere. To this end, the chamber 100 may include an exhaust port 102 formed therein. The exhaust port 102 may be formed in the chamber bottom 112. The exhaust port 102 is connected to a vacuum pump P via an exhaust line 104 and an exhaust valve 103. The pressure in the processing space S in the chamber 100 may be adjusted to a predetermined pressure by operating the vacuum pump P and adjusting the exhaust valve 103.

An opening 106 may be formed in the chamber sidewall 111. The opening 106 functions as a passage through which a substrate W enters and exits the chamber. An opening/closing door 108 is mounted at a position corresponding to the opening 106. The opening/closing door 108 functions to open and close the opening 106 of the chamber 100. In a closed state, the opening/closing door 108 hermetically seals the processing space S in the chamber 100. In addition, in an open state, the opening/closing door 108 allows transfer of the substrate W from a transfer space outside the chamber 100 into the processing space S or from the processing space S into the transfer space outside the chamber 100. The opening/closing door 108 may be a gate valve.

Inside the chamber 100, a substrate support unit 200 is provided to support the substrate W. The substrate support unit 200 may include an electrostatic chuck 220 configured to adsorb and fix the substrate W and a base plate 210 configured to support the electrostatic chuck 220. The electrostatic chuck 220 and the base plate 210 may be bonded to each other by a bonding layer 230, and the bonding layer 230 may be formed of silicone or the like.

The electrostatic chuck 220 may be configured as a dielectric plate formed of alumina or the like, and may be provided therein with a chuck electrode 222 configured to generate electrostatic force. When voltage is applied to the chuck electrode 222 by a power supply (not shown), electrostatic force is generated, and accordingly, the substrate W is adsorbed on and fixed to the electrostatic chuck 220. The electrostatic chuck 220 may be provided with a heater 224 to adjust the temperature of the substrate W. The electrostatic chuck 220 does not necessarily include the heater 224, and the heater 224 may be selectively employed.

The base plate 210 may be located below the electrostatic chuck 220 and may be formed of a metal such as aluminum. The base plate 210 may be provided therein with a coolant channel 212 through which a cooling fluid flows, and thus may perform a function of cooling the substrate W. The coolant channel 212 may be provided as a circulation passage through which the cooling fluid circulates.

In addition, the substrate support unit 200 may include a heat transfer gas channel 214 to supply a heat transfer gas from a heat transfer gas source 216 to a back surface of the substrate W. The heat transfer gas may facilitate heat transfer between the substrate W and the base plate 210 to promote cooling of the substrate W. Helium (He) may be used as the heat transfer gas.

The substrate support unit 200 may include a ring member 240 surrounding the outer periphery of the electrostatic chuck 220. The ring member 240 may include a stepped portion formed on an upper side thereof in order to support the outer circumferential surface of the substrate W. The ring member 240 may be formed of a ceramic material and may be a focus ring.

The gas supply unit 300 supplies gas required for substrate processing to the inside of the chamber 100. The gas supply unit 300 may include a gas source 310, a gas supply line 312, a gas supply valve 314, a gas spray nozzle 318, and a showerhead 320. The gas supply line 312 connects the gas source 310 to the gas spray nozzle 318, and the gas supply valve 314 is mounted on the gas supply line 312 to open and close the passage or to adjust a flow rate of a fluid flowing through the passage. Gas sprayed from the gas spray nozzle 318 is supplied to a space between the chamber cover 113 and the showerhead 320, and is then supplied to the processing space S through a gas injection hole 322 formed in the showerhead 320.

Although one gas source 310, one gas supply line 312, and one gas supply valve 314 are illustrated in FIG. 1, the gas supply unit 300 of the present disclosure may include a plurality of gas sources configured to supply a plurality of gases to the inside of the chamber 100 and a plurality of gas supply valves configured to independently control supply of the respective gases. The plurality of gases may include a process gas used in the substrate processing operation, for example, an etching gas, and may include an inert gas for purging.

The plasma generating unit 500 may include radio-frequency (RF) power supplies 510 and 520 configured to supply RF power in order to generate plasma in the processing space S. The RF power supplies 510 and 520 may supply RF power in a range from f₁ kHz to f₂ MHz.

The RF power supply 510 may supply RF power to an upper electrode, and the showerhead 320 may function as the upper electrode. The RF power supply 520 may supply RF power to a lower electrode, and the substrate support unit 200 may function as the lower electrode. Although the RF power supplies 510 and 520 are illustrated in FIG. 1 as being connected to the upper electrode and the lower electrode, respectively, this configuration should be understood as an example. In order to generate plasma in the processing space S, the upper electrode may be grounded, and RF power may be applied only to the lower electrode from the RF power supply 520, which is a lower power supply. Alternatively, RF power may be applied to the upper electrode from the RF power supply 510, which is an upper power supply, and the lower electrode may be grounded. Alternatively, RF power may be applied to both the upper electrode and the lower electrode. A plurality of RF power supplies having different frequencies may be used as the lower power supply.

The RF power supplies 510 and 520 may continuously apply power or may apply power in a pulse mode.

The electromagnet unit 400 is disposed above the chamber 100 to generate a magnetic field in the processing space S. The electromagnet unit 400 may include an electromagnet power supply 403, a coil module 410, a variable core 420, an electromagnet cooling unit 460, and a housing 401.

The electromagnet power supply 403 includes a DC power supply configured to supply direct current to the coil module 410. When the electromagnet power supply 403 supplies direct current to the coil module 410, current flows through the coil, and a magnetic field is generated in the processing space S. By controlling the current supplied to the coil module 410, the magnetic field generated in the processing space S may be varied, thereby enabling control of the density distribution of the plasma generated in the processing space S.

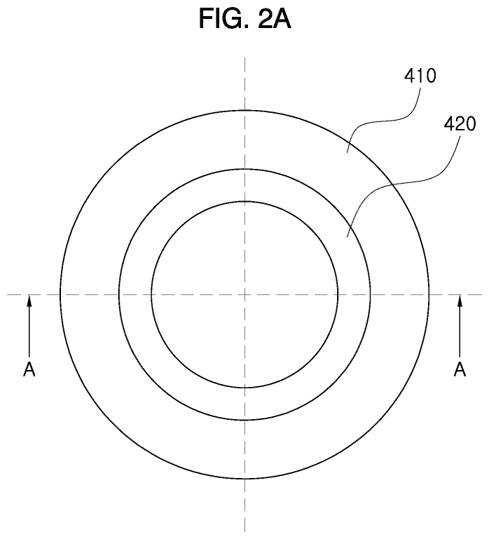

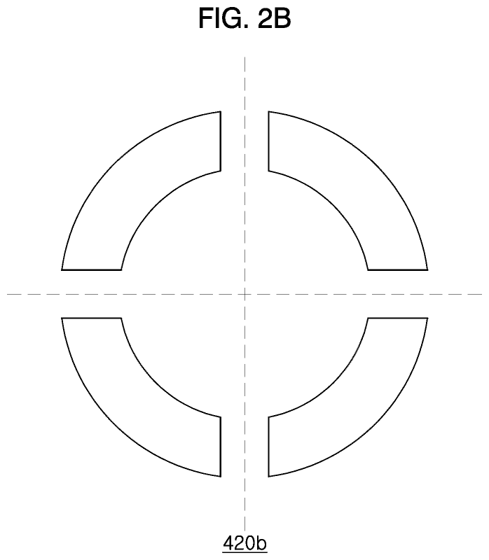

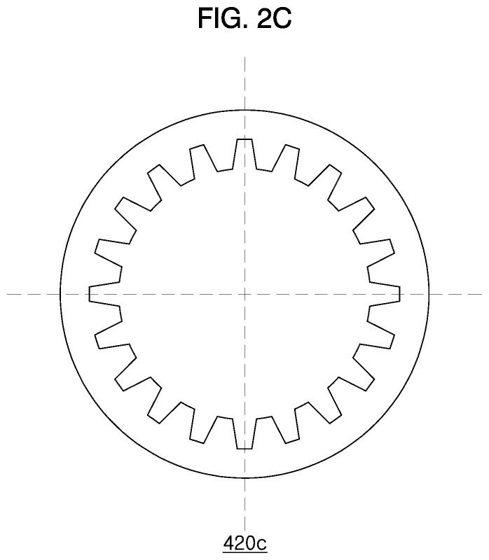

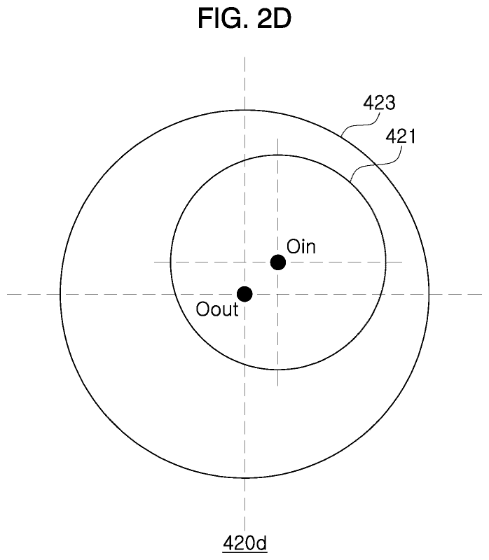

The coil module 410 is connected to the electromagnet power supply 403 to receive current, thereby generating a magnetic field in the processing space S. The variable core 420 is mounted adjacent to the coil module 410 and is magnetized by the magnetic field generated by the coil module 410 to generate an induced magnetic field. Detailed descriptions of the coil module 410 and the variable core 420 will be given later with reference to FIGS. 2 to 4.

The electromagnet cooling unit 460 controls the temperature of the coil module 410 that generates the magnetic field. In particular, the electromagnet cooling unit 460 operates based on temperature information obtained from the coil module 410, thereby enabling the coil module 410 to stably generate and maintain the magnetic field in the processing space S.

The electromagnet cooling unit 460 includes a temperature detection sensor 461, a cooling fin 463, and a cooling fan 465. The temperature detection sensor 461 is located inside or near the coil module 410 to detect the temperature of the coil module 410. In particular, the temperature detection sensor 461 may be mounted adjacent to a portion of the coil module 410 at which a wire is electrically connected and substantial heat is generated. Furthermore, the temperature detection sensor 461 is connected to the controller 600 to transmit the detected temperature of the coil module 410 to the controller 600.

The cooling fin 463 may be provided in contact with the coil module 410. That is, the cooling fin 463 may conduct heat generated in the coil module 410 and may release the heat outside. The cooling fin 463 may include a plurality of fin structures formed to extend in an outward direction from a center portion so as to increase a surface area.

The cooling fan 465 may be located in the outward direction of the cooling fin 463 to discharge air heated by the heat released from the cooling fin 463 to the outside or to supply a gas from the outside to cool the cooling fin 463. For example, the cooling fan 465 may be supplemented with a vortex system nozzle configured to supply high-pressure air rotating rapidly in a spiral form. In another example, the cooling fan 465 may be connected to a cooling gas supply device to supply a cooling gas to the inside of the housing 401.

In one example, the cooling fan 465 may be located at a position spaced a predetermined distance from the coil module 410 and the variable core 420. That is, the cooling fan 465 may be mounted at a predetermined distance upward from the coil module 410 and the variable core 420 so that the magnetic field generated by the coil module 410 and the variable core 420 is not disturbed by the cooling fan 465.

Although the cooling fin 463 is illustrated in FIG. 1 as being integrated with the electromagnet unit 400, the present disclosure is not limited thereto. That is, the electromagnet cooling unit 460 may be provided in a form that is detachable and attachable as needed.

In addition, although the electromagnet cooling unit 460 has been described above as being of an air-cooling type, the present disclosure is not limited thereto. If necessary, the electromagnet cooling unit 460 may employ a water-cooling type cooling device using a coolant including process cooling water (PCW) or the like.

The housing 401 may be a cover that protects the coil module 410, the variable core 420, and the electromagnet cooling unit 460 disposed therein from the outside. Alternatively, the housing 401 may be a shielding cover that blocks transfer of a magnetic field generated therein to a space other than the processing space S. The housing 401 may be selectively employed in the substrate processing apparatus 10 as needed.

The controller 600 may be connected to the respective units of the substrate processing apparatus 10 to control the substrate processing operation. In particular, the controller 600 may be connected to the electromagnet power supply 403, the coil module 410, and the electromagnet cooling unit 460 to control the electromagnet unit 400. In addition, although not shown, the controller 600 may include an interlock module connected to the electromagnet unit 400. For example, in the event of an abnormality during the substrate processing operation of the substrate processing apparatus 10, the interlock module may detect the abnormality and may stop the substrate processing operation through the controller 600. The controller 600 may include a processor that executes instructions for control of the substrate processing operation.

In one example, the controller 600 may be connected to the temperature detection sensor 461 of the electromagnet cooling unit 460 to receive temperature data of the coil module 410. Furthermore, the controller 600 may control operation of the cooling fan 465 according to the temperature of the coil module 410. In addition, the controller 600 may be connected to the electromagnet power supply 403 to control the magnitude of the current supplied to the coil module 410. Alternatively, the substrate processing apparatus 10 may further include a driving unit (not shown) configured to adjust the position of the variable core 420, and the controller 600 may be connected to the driving unit (not shown) to control the position of the variable core 420.

FIGS. 2A to 2D are top views of various embodiments of the coil module and the variable core according to the present disclosure.

The coil module 410 and the variable core 420 according to an embodiment of the present disclosure will now be described with reference to FIG. 2A.

In one example, the coil module 410 may be provided in a form in which a coil is wound on a bobbin. The bobbin may be formed in an annular shape and may be made of a material that allows a magnetic field to pass therethrough. For example, the bobbin may include a non-magnetic material such as aluminum. The coil module 410 of the present disclosure is not limited to the form in which a coil is wound on a bobbin. For example, the coil module 410 may be provided with only a wound coil excluding the bobbin, in which case an air gap is formed in place of the bobbin.

Although the coil module 410 has been described above as being provided with a single coil, the present disclosure is not limited thereto. For example, the coil module 410 may include a plurality of coils as needed to generate a magnetic field in the processing space S. Furthermore, a plurality of coil modules 410 may individually receive current from the electromagnet power supply, thereby adjusting the intensities of magnetic fields in respective regions. Furthermore, the coil module 410 may adjust the intensity of the magnetic field by varying the number of windings of each coil. For example, when the coil module 410 includes a first coil and a second coil having fewer windings than the first coil, the controller 600 may perform control such that the magnetic field intensity is mainly tuned through the first coil and is finely tuned through the second coil.

The variable core 420 may be provided adjacent to the coil module 410, thereby more precisely controlling plasma density distribution in the processing space S. The variable core 420 may be formed in a shape having an open center. For example, the variable core 420 may be formed in an annular shape in which a through-hole is formed at the center. Alternatively, the variable core 420 may be formed in a cylindrical shape as needed.

In one example, the variable core 420, which is annular, may be inserted into the coil module 410. The variable core 420 may have an outer diameter equal to the inner diameter of the coil module 410. Alternatively, the outer diameter of the variable core 420 may be less than the inner diameter of the coil module 410 so that a gap is defined between an outer surface of the variable core 420 and an inner surface of the coil module 410. Although the variable core 420 has been described above as being disposed inside the coil module 410, the present disclosure is not limited thereto. For example, if necessary, the variable core 420 may have an inner diameter greater than the outer diameter of the coil module 410 and may be disposed outside the coil module 410.

Although the variable core 420 is illustrated in FIG. 2A as being provided singularly, the present disclosure is not limited thereto. That is, the variable core 420 may be provided in plural as needed. For example, a plurality of variable cores 420 may be provided inside the coil module 410. Alternatively, at least one variable core 420 may be provided outside the coil module 410, and at least one variable core 420 may be provided inside the coil module 410. The number of coil modules 410 and the number of variable cores 420 may be equal to or different from each other.

In one example, the variable core 420 may be formed of a material having high magnetic permeability. For example, the variable core 420 may be formed of an alloy containing an element such as nickel (Ni), iron (Fe), silicon (Si), or cobalt (Co) or of a heat-treated material. In particular, a ferromagnetic material (e.g., ferrite) including nickel (Ni), iron (Fe), or the like may be used as a material of the variable core 420.

The magnetic permeability of the variable core 420 may be set to be higher than that of the coil module 410. In addition, when a plurality of variable cores 420 is provided in the electromagnet unit 400, the variable cores 420 may be formed to have the same magnetic permeability or different magnetic permeabilities as needed. For example, when the plurality of variable cores 420 has first magnetic permeability and second magnetic permeability, which is higher than the first magnetic permeability, respectively, the magnetic field may be controlled such that the magnetic field distribution is mainly tuned by adjusting the position of the variable core 420 having the first magnetic permeability and such that the magnetic field distribution is finely tuned by adjusting the position of the variable core 420 having the second magnetic permeability.

The variable core 420 may be magnetized by the magnetic field generated by the coil module 410 to which current is supplied, thereby generating an induced magnetic field. That is, the variable core 420 may generate an induced magnetic field to change the magnetic field distribution in the processing space S. For example, the annular variable core 420 may be magnetized by the coil module 410, so that the coil module 410 concentrates magnetic flux on upper and lower ends of the ring, thereby changing the magnetic field distribution in the processing space S. In particular, the distribution of the magnetic field generated by the coil module 410 may be varied so that magnetic flux density is concentrated in the variable core 420 having low magnetic resistance or magnetic reluctance. Furthermore, the variable core 420 may relatively increase or amplify the intensity of the magnetic field compared to a configuration without the variable core 420.

The variable core 420 may be provided in a cartridge form. That is, the variable core 420 may be replaced and used according to the substrate processing operation being performed. In the substrate processing apparatus 10, the distribution of the magnetic field and the plasma formed in the processing space S may be changed by replacing the variable core 420 without changing other setting values or recipes. Furthermore, the variable core 420 may be provided in various shapes. For example, the variable core 420 may be formed in a symmetric shape, or may be formed in an asymmetric shape to asymmetrically form and control the distribution of the magnetic field.

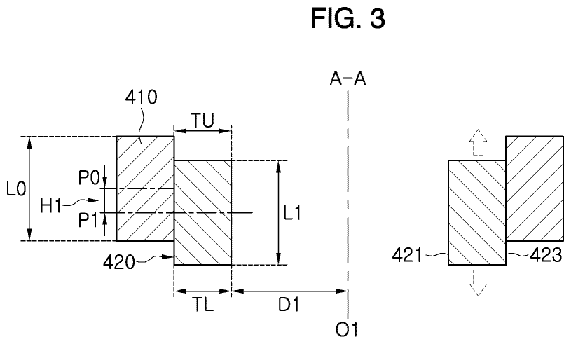

Hereinafter, other embodiments of the variable core employed in the present disclosure will be described with reference to FIGS. 2B to 2D and 3.

In one example, referring to FIG. 2B, the variable core 420b may be provided in a divided form. That is, the variable core 420b may be provided only in a specific region of the electromagnet unit 400, and accordingly, the substrate processing apparatus 10 may perform control such that plasma is concentrated in a specific region of the substrate W. For example, the variable core 420b may be provided in the form of a segmented ring. As shown in FIG. 2B, the variable core 420b may be provided in a form divided into four parts. Alternatively, the variable core 420b may be provided in a form divided into n (n being a natural number of 2 or greater) parts as needed. In another example, only a part of the segmented ring of the variable core 420b may be selectively provided.

In another example, referring to FIG. 2C, the variable core 420c may include a groove formed in the side surface thereof. For example, the variable core 420c may include at least one groove formed in a vertical direction in the inner side surface thereof. In addition, unlike the illustrated example, the variable core 420c may include at least one groove formed in the vertical direction in the outer side surface thereof.

In another example, referring to FIG. 2D, the variable core 420d may be provided in an eccentric ring shape in which the center of a circle forming an inner side surface 421 and the center of a circle forming an outer side surface 423 do not coincide with each other. For example, the variable core 420d may be provided in an annular shape having a hollow portion, in which the center Oin of the inner diameter is offset from the center Oout of the outer diameter. In this case, the plasma in the processing space may be dispersed with respect to the center Oin of the inner diameter, unlike the conventional configuration in which the plasma is dispersed with respect to the center Oout of the outer diameter.

Although the variable core 420 has been described above as being provided in an annular shape including a circumferential surface, the present disclosure is not limited thereto. That is, depending on the desired plasma distribution, the outer and/or inner sides of the variable core 420 may be formed in a polygonal shape or in an asymmetric shape when viewed in cross-sectional view.

FIG. 3 is a longitudinal-sectional view of the coil module and the variable core taken along line A-A in FIG. 2A.

Various exemplary embodiments of the variable core 420 that is applicable in a cartridge form will now be described with reference to FIG. 3.

In one example, variable cores 420 having different core lengths L1, core lower-end thicknesses TL, core upper-end thicknesses TU, inner diameters D1, and magnetic permeabilities may be provided. Depending on the desired plasma distribution in the substrate processing apparatus 10, a variable core 420 having appropriate specifications may be selected. In addition, the substrate processing apparatus 10 may precisely control the plasma distribution by adjusting the core vertical displacement H1 of the variable core 420, that is, by moving the variable core 420 in the vertical direction.

For example, the variable core 420 may have a core length L1, which is a length in the vertical direction that is adjustable. That is, the length L1 of the variable core 420 may be set to be equal to the vertical length L0 of the coil module 410. Alternatively, the length L1 of the variable core 420 may be set to be greater or less than the vertical length L0 of the coil module 410.

In another example, the variable core 420 may have a core lower-end thickness TL and a core upper-end thickness TU that are adjustable. That is, the core lower-end thickness TL and the core upper-end thickness TU of the variable core 420 may be set to be equal to each other. Alternatively, the core lower-end thickness TL may be set to be greater or less than the core upper-end thickness TU. That is, the variable core 420 may be provided in a conical shape or an inverted conical shape.

In addition, the variable core 420 may have an inner diameter D1 that is adjustable. That is, the thickness and inner diameter D1 of the variable core 420 may be adjusted so that the outer side surface 423 thereof is in contact with the inner side of the coil module 410. Alternatively, the variable core 420 may be formed such that the outer side surface 423 thereof is spaced apart from and forms a gap with the inner side of the coil module 410.

As described above, the substrate processing apparatus 10 may control the distribution of the magnetic field formed in the processing space S by adjusting the core vertical displacement H1 of the variable core 420. For example, the core vertical displacement H1, which is a distance from a vertical reference point P0 corresponding to a middle point of the coil module 410 in the vertical direction (or the Z-axis direction) to a core reference point P1 corresponding to a middle point of the variable core 420 in the vertical direction, may be adjusted to be zero. Alternatively, the variable core 420 may be lowered such that the core vertical displacement H1 becomes a negative value or may be raised such that the core vertical displacement H1 becomes a positive value.

In one example, the substrate processing apparatus 10 may further include a driving unit (not shown) configured to adjust the core vertical displacement H1 of the variable core 420. The driving unit (not shown) may receive a signal from the controller 600, and may adjust the position of the variable core 420 in the vertical direction. Furthermore, the driving unit (not shown) may be configured to adjust the position of the variable core 420 in a horizontal direction as needed.

The substrate processing apparatus 10 may control the distribution of the magnetic field and the plasma formed in the processing space S by adjusting the core vertical displacement H1 of the variable core 420. For example, the variable core 420 may be lowered to increase the intensity of the magnetic field formed on the substrate W. Alternatively, the variable core 420 may be raised to reduce the intensity of the magnetic field formed on the substrate W. However, the adjustment of the placement of the variable core 420 is not limited to controlling the intensity of the magnetic field. The substrate processing apparatus 10 may adjust the core vertical displacement H1 and the horizontal displacement of the variable core 420 in order to control the distribution of the magnetic field formed in each region of the processing space S.

In another example, the variable core 420 may be replaced with another variable core having different magnetic permeability. That is, by replacing the variable core 420 with a core having higher or lower magnetic permeability, the distribution of the magnetic field formed in the substrate processing apparatus 10 may be adjusted.

The variable core 420 may be manually replaced before or after the substrate processing operation is performed. Alternatively, although not shown, the variable core 420 may be replaced by a replacement device configured to automatically replace the variable core 420.

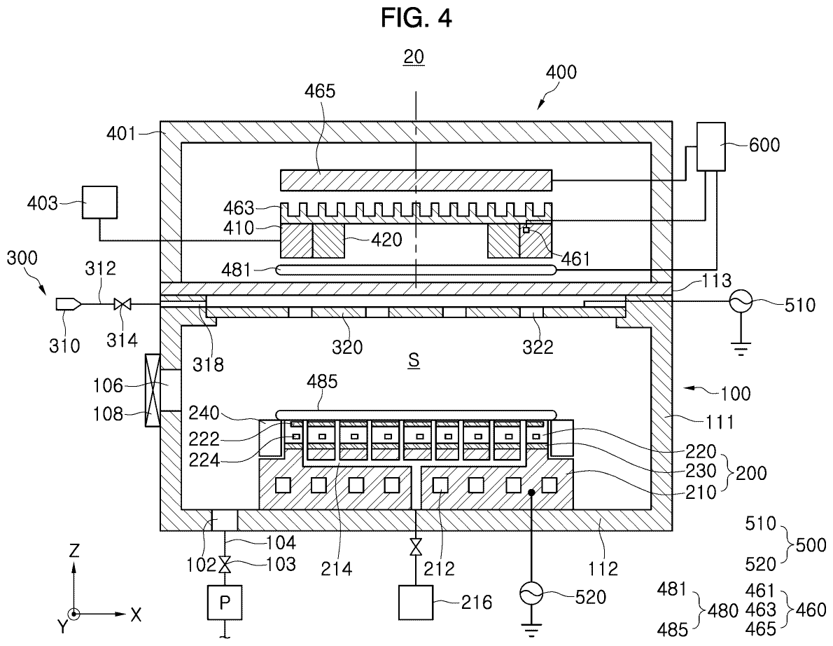

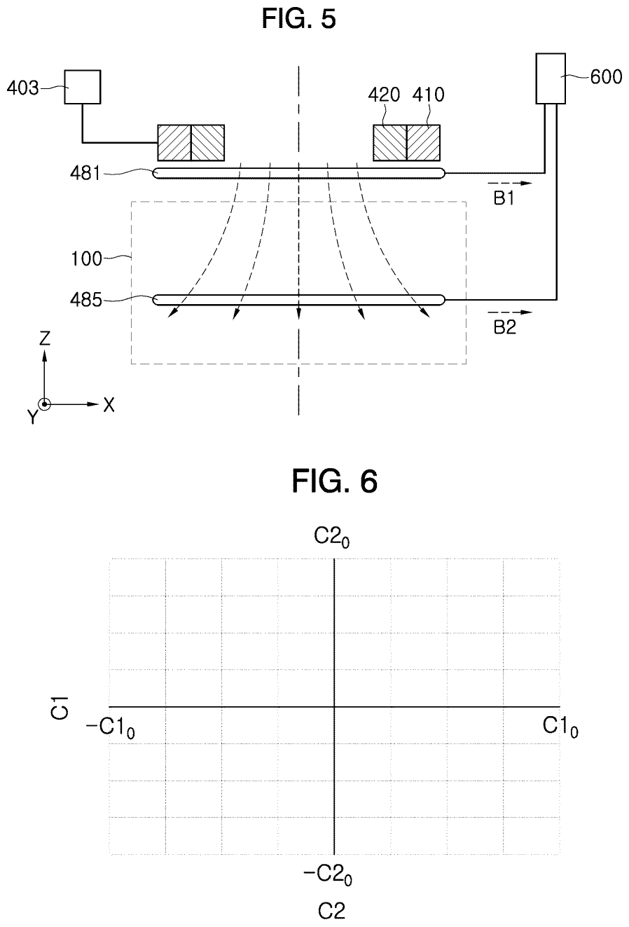

FIG. 4 is a view showing the configuration of a substrate processing apparatus according to another embodiment of the present disclosure, and FIG. 5 is a view schematically showing operation of a magnetic field measurement module 480 according to another embodiment of the present disclosure.

Referring to FIGS. 4 and 5, the substrate processing apparatus 20 may further include a magnetic field measurement module 480 in addition to the components of the substrate processing apparatus 10 shown in FIG. 1. The magnetic field measurement module 480 includes a first magnetic field measurement sensor 481 provided in a first region, which is a region below the coil module 410 and the variable core 420, and a second magnetic field measurement sensor 485 provided in a second region, which is a region above the electrostatic chuck 220. Each of the first magnetic field measurement sensor 481 and the second magnetic field measurement sensor 485 may include at least one Hall sensor. In particular, each of the first magnetic field measurement sensor 481 and the second magnetic field measurement sensor 485 may be formed in a circular shape and may include a plurality of sensors arranged in a radial direction from the center to the edge. In addition, the first magnetic field measurement sensor 481 and the second magnetic field measurement sensor 485 may be designed to withstand pressure so as not to be damaged by pressure variations.

The first magnetic field measurement sensor 481 may be located in a first region, which is a region below the coil module 410 and the variable core 420, and may obtain first magnetic field data B1 representing the intensity of the magnetic field in the first region. In particular, the first magnetic field measurement sensor 481 may measure the intensity of the magnetic field in the first region before the substrate processing operation is performed. Furthermore, the first magnetic field measurement sensor 481 may also measure the intensity of the magnetic field in the first region while the substrate processing operation is in progress.

The first magnetic field measurement sensor 481 may transmit the measured first magnetic field data B1 to the controller 600. In particular, the first magnetic field measurement sensor 481 may transmit the measured first magnetic field data B1 to the controller 600 in real time.

The second magnetic field measurement sensor 485 may be located in a second region, which is a region above the electrostatic chuck, and may measure second magnetic field data B2 representing the intensity of the magnetic field in the second region. In particular, the second magnetic field measurement sensor 485 may be transferred into the chamber 100 before the substrate processing operation is performed, and may measure the magnetic field in the second region. However, the second magnetic field measurement sensor 485 is transferred out of the chamber 100 before the substrate processing operation is performed. The second magnetic field measurement sensor 485 may be transferred from the outside to the inside of the chamber 100 or vice versa by a substrate transfer robot. In one example, the second magnetic field measurement sensor 485 may include a battery and a memory embedded therein, thereby cumulatively storing the magnetic field data measured in the second region.

The second magnetic field measurement sensor 485 may be connected to the controller 600 and may transmit the obtained second magnetic field data B2 to the controller 600. In one example, the second magnetic field measurement sensor 485 may include a wireless communication module in the form of a substrate to transmit the second magnetic field data B2 to the controller 600.

The substrate processing apparatus 20 obtains, before the substrate processing operation is performed, a correlation between the current supplied from the electromagnet power supply 403 and the intensity of the magnetic field formed in the substrate processing apparatus 20. In one example, the substrate processing apparatus 20 may measure and store the intensity of the magnetic field formed in the first region and the intensity of the magnetic field formed in the second region according to the current applied to the coil module 410. In more detail, when the electromagnet power supply 403 supplies a constant current to the coil module 410, the substrate processing apparatus 20 may obtain a result value of the first magnetic field data B1 measured by the first magnetic field measurement sensor 481 and a result value of the second magnetic field data B2 measured by the second magnetic field measurement sensor 485. Furthermore, the substrate processing apparatus 20 may analyze a correlation between the current supplied to the coil module 410, the first magnetic field data B1, and the second magnetic field data B2, thereby obtaining a profile of the magnetic field formed in each region according to the supplied current.

The substrate processing apparatus 20 may derive, based on the previously obtained profile of the magnetic field, the intensity of the magnetic field actually formed on the substrate W during the substrate processing operation. In more detail, the substrate processing apparatus 20 may derive, based on the magnitude of the current supplied to the coil module 410 and the first magnetic field data B1 measured in the first region, the intensity of the magnetic field formed in the second region in which the substrate W is located. That is, unlike the related art in which the intensity of the magnetic field formed in the second region according to the current supplied to the coil module 410 is derived using simulation, the substrate processing apparatus 20 of the present disclosure may construct a magnetic field profile in advance and may refer to second magnetic field data B2 corresponding to the first magnetic field data B1, thereby more accurately deriving the intensity of the magnetic field formed in the second region. In particular, the substrate processing apparatus 20 exhibits an effect of deriving the intensity of the magnetic field formed on the substrate W in the state in which the second magnetic field measurement sensor 485 is transferred outside from the second region during the substrate processing operation.

Furthermore, the substrate processing apparatus 20 may determine, based on the correlation of the first magnetic field data B1 according to the magnitude of the current supplied to the coil module 410, whether a magnetic field is normally formed in the substrate processing apparatus 20. That is, the substrate processing apparatus 20 may compare converted current derived/converted from the first magnetic field data B1 measured in the first region with input current supplied to the coil module 410, thereby determining whether a magnetic field is normally formed in the second region by the electromagnet unit 400. Alternatively, the substrate processing apparatus 20 may determine whether a magnetic field is normally formed in the second region with respect to other factors for adjusting the magnetic field. A more detailed description of a magnetic field inspection process will be given later with reference to FIG. 8.

In the substrate processing apparatus 20, at least one control parameter may be selected from among adjustment factors of the variable core 420 as a control parameter for deriving a magnetic field profile. For example, in the substrate processing apparatus 20, the core vertical displacement H1 of the variable core 420 may be selected in place of current supplied to the coil module 410. Alternatively, in the substrate processing apparatus 20, the core length L1, the core lower-end thickness TL, the core upper-end thickness TU, the inner diameter D1, the magnetic permeability of the variable core 420 may be selected as the control parameter.

Furthermore, as the control parameter is selected from among the adjustment factors of the variable core 420, the substrate processing apparatus 20 may determine whether a magnetic field is normally formed in first and second regions according to the selected control parameter. For example, when the core vertical displacement H1 is selected as the control parameter, the substrate processing apparatus 20 may compare the core vertical displacement H1 derived/converted from the first magnetic field data B1 with the actual core vertical displacement H1, thereby determining whether a magnetic field is normally formed in the second region.

FIG. 6 is a window map representing a combination of control parameters configured to obtain a magnetic field profile in the substrate processing apparatus when a plurality of control parameters is selected in an embodiment of the present disclosure. As described above, the number of coil modules 410 may be one or greater. However, the window map of FIG. 6 exemplarily represents a configuration in which two coil modules 410 are provided. A first control parameter C1 of the X axis represents current applied to one of the coil modules 410. A second control parameter C2 of the Y axis represents current applied to the other of the coil modules 410. The coil modules 410 described above may have different outer diameters and may be disposed such that the centers thereof are aligned with each other when viewed from above the substrate processing apparatus 20. The substrate processing apparatus 20 may select arbitrary values as two control parameters within the window map shown in FIG. 6 to form a magnetic field profile. For example, the substrate processing apparatus 20 may measure the intensities of the magnetic fields in the first region and the second region at each point within the illustrated window map. That is, the substrate processing apparatus 20 may obtain the first magnetic field data B1 from the first magnetic field measurement sensor 481 and may obtain the second magnetic field data B2 from the second magnetic field measurement sensor 485 while adjusting the first control parameter C1 in predetermined steps within a range of [−C1₀, C1₀] and adjusting the second control parameter C2 in steps within a range of [−C2₀, C2₀], thereby obtaining a magnetic field profile corresponding to the window map. In this case, when the first control parameter C1 or the second control parameter C2 is adjusted to zero, current applied to a corresponding coil module 410 may be turned off to zero. In addition, when the first control parameter C1 or the second control parameter C2 is adjusted so that the positive/negative (+/−) sign thereof is changed, the phase of the current applied to the corresponding coil module 410 may be changed. As the step in which each control parameter is adjusted in a certain region of the window map varies, the number of magnetic field points measured in a specific region of the window map may increase or decrease.

The control parameters according to the embodiment of the present disclosure are not limited to the examples shown in FIG. 6. In one example, the substrate processing apparatus 20 may select input current supplied to the coil module 410 and the core vertical displacement H1 of the variable core 420 as the first control parameter C1 and the second control parameter C2. Furthermore, the substrate processing apparatus 20 may measure the first magnetic field data B1 and the second magnetic field data B2 according to the current supplied to the coil module 410 and the core vertical displacement H1 of the variable core 420, thereby deriving the profile of the magnetic field formed according to the current and the core vertical displacement H1. In this case, the magnetic field profile may be obtained by the first magnetic field measurement sensor 481 and the second magnetic field measurement sensor 485 before the substrate processing operation is performed.

Although it has been described above that the number of control parameters to be selected is two, the present disclosure is not limited thereto. If necessary, at least one control parameter may be selected from among input current supplied to the coil module 410 and factors for determining the shape of the variable core 420, such as a length, a thickness, and a diameter.

Furthermore, as a plurality of control parameters is selected, the substrate processing apparatus 20 may determine whether a magnetic field is normally formed in the first and second regions according to the selected control parameters.

For example, in the substrate processing apparatus 20 in which the input current supplied to the coil module 410 and the core vertical displacement H1 are selected as the first control parameter C1 and the second control parameter C2, the substrate processing apparatus 20 may determine whether a magnetic field is normally formed in the second region by comparing the input current supplied to the coil module 410 with the converted current derived/converted from the first magnetic field data B1 and/or by comparing the current core vertical displacement H1 with the core vertical displacement H1 derived/converted from the first magnetic field data B1.

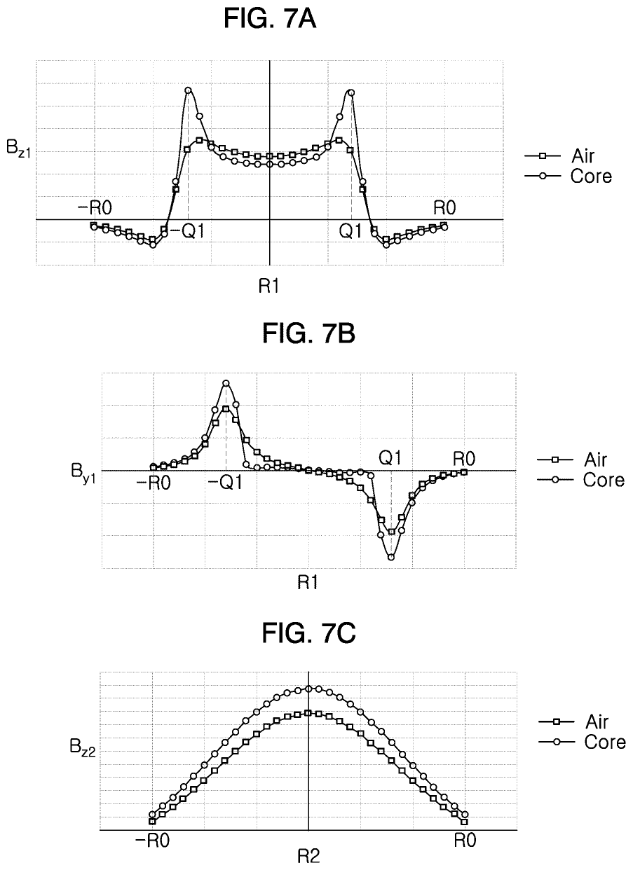

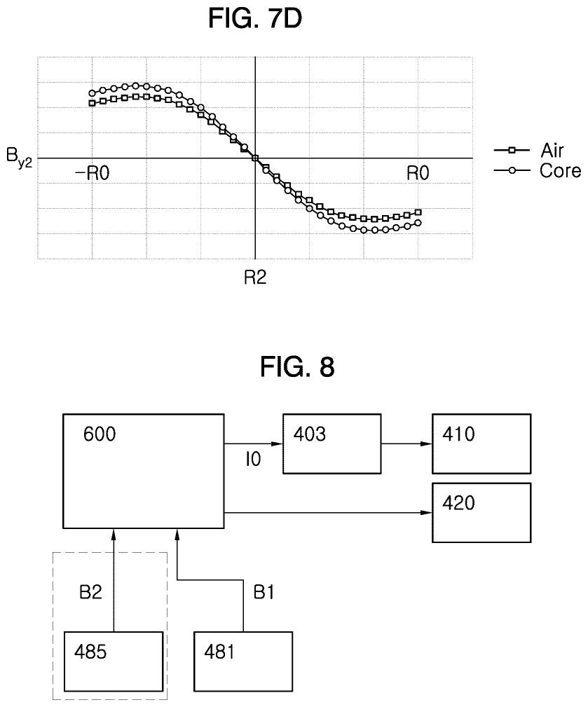

FIGS. 7A to 7D are graphs showing variations in magnetic field intensity depending on the presence or absence of the variable core in the substrate processing apparatus shown in FIG. 5.

In one example, in order to compare a case (Core) in which an annular variable core 420 is provided at a position spaced a distance Q1 from the center of the annular coil module 410 with a case (Air) in which an air gap is formed without the variable core 420, the substrate processing apparatus 20 measures magnetic field intensity using the first magnetic field measurement sensor 481 and the second magnetic field measurement sensor 485.

FIG. 7A shows first Z-axis magnetic field intensity B_{z1}, which is magnetic field intensity in the Z-axis direction measured within a range of (−R0, R0) along a radial displacement R1 from the center of the first magnetic field measurement sensor 481 with respect to the YZ plane, and FIG. 7B shows first Y-axis magnetic field intensity B_{y1}, which is magnetic field intensity in the Y-axis direction measured within the range of (−R0, R0) along the radial displacement R1 from the center of the first magnetic field measurement sensor 481 with respect to the YZ plane.

Referring to FIG. 7A, it may be confirmed that, when the variable core 420 is provided in the substrate processing apparatus 20 (Core), the first Z-axis magnetic field intensity B_{z1} increases at a point Q1 or −Q1 spaced apart from the center, compared to when the variable core 420 is not provided (Air). On the other hand, it may be confirmed that, when the variable core 420 is provided, the first Z-axis magnetic field intensity B_{z1} decreases in a predetermined section adjacent to the center with respect to the point Q1 or in a predetermined section distant from the center with respect to the point Q1.

Referring to FIG. 7B, it may be confirmed that, when the variable core 420 is provided in the substrate processing apparatus 20 (Core), the first Y-axis magnetic field intensity B_{y1} increases at the point Q1 or −Q1 spaced apart from the center, compared to when the variable core 420 is not provided (Air). On the other hand, it may be confirmed that the first Y-axis magnetic field intensity B_{y1} decreases in a predetermined section adjacent to the center with respect to the point Q1.

That is, according to the results shown in FIGS. 7A and 7B, when the variable core 420 is provided in the substrate processing apparatus 20, the magnetic field distribution may be concentrated at a position at which the variable core 420 is located.

FIG. 7C shows second Z-axis magnetic field intensity B_{z2}, which is magnetic field intensity in the Z-axis direction measured within the range of (−R0, R0) along a radial displacement R2 from the center of the second magnetic field measurement sensor 485 with respect to the YZ plane, and FIG. 7D shows second Y-axis magnetic field intensity B_{y2}, which is magnetic field intensity in the Y-axis direction measured within the range of (−R0, R0) along the radial displacement R2 from the center of the second magnetic field measurement sensor 485 with respect to the YZ plane.

Referring to FIGS. 7C and 7D, it may be confirmed that, when the variable core 420 is provided in the substrate processing apparatus 20 (Core), the absolute values of the second Z-axis magnetic field intensity B_{z2} and the second Y-axis magnetic field intensity B_{y2} are greater in the entire region than when the variable core 420 is not provided (Air). That is, when the variable core 420 is provided in the substrate processing apparatus 20, the magnetic field intensity may be varied in the second region in which the substrate W is processed.

FIG. 8 is a block diagram showing some components including the controller for adjusting a magnetic field in the substrate processing apparatus shown in FIG. 4.

In one example, the substrate processing apparatus 20 may control the substrate processing operation using the electromagnet unit 400 through the controller 600. The controller 600 may supply input current I0 to the coil module 410 by applying a signal to the electromagnet power supply 403. In addition, the controller 600 may include a driving unit (not shown) to adjust the core vertical displacement H1 of the variable core 420, or may include a replacement unit (not shown) to replace the variable core 420 with another having a different shape or magnetic permeability.

The controller 600 may be connected to the magnetic field measurement module 480 to measure magnetic field intensity in the first region located below the coil module 410 and the variable core 420 and in the second region located above the electrostatic chuck 220. That is, the controller 600 may be connected to the first magnetic field measurement sensor 481 to receive the first magnetic field data B1 and may be connected to the second magnetic field measurement sensor 485 to receive the second magnetic field data B2. For example, the second magnetic field measurement sensor 485 may include a wireless communication device configured to transmit data in a wireless manner, thereby transmitting the second magnetic field data B2 to the controller 600. The second magnetic field measurement sensor 485 is disposed in the second region and is connected to the controller 600 before the substrate processing operation is performed. Then, the substrate processing apparatus transfers the second magnetic field measurement sensor 485 to the outside to retrieve the same before the substrate processing operation is performed.

The controller 600 may construct a magnetic field profile formed according to control parameters before the substrate processing operation is performed. In one example, the controller 600 selects at least one control parameter C as a control parameter for adjusting a magnetic field, including the input current I0, the shape of the variable core 420, and the core vertical displacement H1. The controller 600 forms a magnetic field in the first and second regions of the substrate processing apparatus 20 by applying a signal to the electromagnet power supply 403 to supply the input current I0 to the coil module 410. Furthermore, the controller 600 receives the first magnetic field data B1 from the first magnetic field measurement sensor 481 and receives the second magnetic field data B2 from the second magnetic field measurement sensor 485. The controller 600 may construct the magnetic field profile by storing and calculating the first magnetic field data B1 and the second magnetic field data B2 corresponding to the at least one control parameter C.

The controller 600 may determine whether the electromagnet unit 400 is normally operating through the pre-constructed magnetic field profile. In one example, the controller 600 applies a signal to the electromagnet power supply 403 in order to control plasma distribution in the substrate processing region. That is, the controller 600 applies a signal to the electromagnet power supply 403 so that the electromagnet power supply 403 supplies input current I0 corresponding to magnetic field intensity to be formed in the second region to the coil module 410. Alternatively, the controller 600 may change or adjust the variable core 420 in order to control plasma distribution in the substrate processing region. That is, the controller 600 adjusts the control parameter C such as the shape or position of the variable core 420 through the driving unit (not shown) or the replacement unit (not shown) so that desired magnetic field intensity is formed in the second region.

When a magnetic field is formed in the first and second regions through the coil module 410 during the substrate processing operation, the controller 600 receives the first magnetic field data B1 measured in the first region through the first magnetic field measurement sensor 481. Furthermore, the controller 600 calculates a converted parameter, which is a converted value of the control parameter C corresponding to the measured first magnetic field data B1. In addition, the controller 600 may diagnose the state of the electromagnet unit 400 by comparing the actually set control parameter C with the converted parameter.

For example, when the control parameter C is the input current I0, the controller 600 calculates converted current corresponding to the first magnetic field data B1 in the magnetic field profile. Furthermore, the controller 600 may compare the input current I0 input to the electromagnet power supply 403 with the converted current converted from the first magnetic field data B1, thereby determining whether a magnetic field corresponding to the input current I0 is normally formed in the second region by the electromagnet unit 400. That is, the controller 600 may determine whether a magnetic field is normally formed on the substrate in the substrate processing apparatus 20.

When the converted current value exceeds a normal range from the input current I0, the controller 600 may diagnose that the electromagnet unit 400 is in an abnormal state in the currently performed substrate processing operation. Furthermore, upon diagnosing that the electromagnet unit 400 is in an abnormal state, the controller 600 may interrupt the substrate processing operation through the interlock module (not shown). The above-described process of diagnosing the state of the electromagnet unit 400 may be performed in real time during the substrate processing operation. In addition, the substrate processing apparatus 20 may identify a replacement timing of the electromagnet unit 400 through the process of diagnosing the state of the electromagnet unit 400.

As is apparent from the above description, the substrate processing apparatus according to the present disclosure may precisely control magnetic field intensity and distribution formed in a processing region in which a substrate is processed through a variable core disposed adjacent to a coil module.

In particular, the substrate processing apparatus of the present disclosure may easily control magnetic field distribution and intensity by adjusting the position of the variable core or replacing the variable core.

In addition, the substrate processing apparatus of the present disclosure may construct a specific magnetic field profile by measuring magnetic field intensity in a plurality of regions and may derive magnetic field intensity actually formed on the substrate during substrate processing operation.

Furthermore, the substrate processing apparatus of the present disclosure may determine whether an electromagnet unit is normally operating by comparing the pre-constructed magnetic field profile with magnetic field intensity measured during the substrate processing operation.

The effects achievable through the present disclosure are not limited to the above-mentioned effects, and other effects not mentioned herein will be clearly understood by those skilled in the art from the above description.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A substrate processing apparatus configured to perform plasma processing on a substrate, the substrate processing apparatus comprising:
a chamber having a processing space defined therein to process the substrate;
a substrate support unit configured to support and fix the substrate disposed thereon;
a gas supply unit comprising a showerhead configured to supply gas to the processing space; and
an electromagnet unit configured to be located above the chamber, and to generate a magnetic field,
wherein the electromagnet unit comprises:
an electromagnet power supply configured to supply power;
a coil module configured to receive power from the electromagnet power supply to generate a magnetic field into the processing space; and
a variable core configured to be magnetized by the magnetic field generated by the coil module, thereby generating a magnetic field, and
wherein the magnetic field formed into the processing space is controlled by replacing the variable core or adjusting a position of the variable core.

2. The substrate processing apparatus as claimed in claim 1,
wherein the variable core is provided inside the coil module.

3. The substrate processing apparatus as claimed in claim 1,
wherein the variable core has higher magnetic permeability than a core of the coil module.

4. The substrate processing apparatus as claimed in claim 1,
wherein the variable core is provided singularly or in plural.

5. The substrate processing apparatus as claimed in claim 2, wherein the variable core is provided in a form of a ring.

6. The substrate processing apparatus as claimed in claim 5,
wherein the variable core is provided in a form of a segmented ring, or a part of the segmented ring is selectively provided.

7. The substrate processing apparatus as claimed in claim 5,
wherein the variable core comprises a groove formed in an inner side surface or an outer side surface of the ring.

8. The substrate processing apparatus as claimed in claim 5,
wherein the variable core is provided in a form of an eccentric ring having an inner center and an outer center different from each other.

9. The substrate processing apparatus as claimed in claim 5,
wherein the variable core is replaced with another variable core having a different shape, including a vertical length, an inner diameter, and a thickness.

10. The substrate processing apparatus as claimed in claim 5,
wherein the variable core is movable in a vertical direction.

11. A substrate processing apparatus configured to perform plasma processing on a substrate, the substrate processing apparatus comprising:
a chamber having a processing space defined therein to process the substrate;
a substrate support unit configured to support and fix the substrate disposed thereon;
a gas supply unit comprising a showerhead configured to supply gas to the processing space;
an electromagnet unit configured to be located above the chamber, and to generate a magnetic field ; and
a controller configured to control a substrate processing operation,
wherein the electromagnet unit comprises:
an electromagnet power supply connected to the controller and configured to supply power;
a coil module configured to receive power from the electromagnet power supply to generate a magnetic field into the processing space; and
a magnetic field measurement module comprising a first magnetic field measurement sensor located in a first region below the coil module and a second magnetic field measurement sensor located in a second region above the substrate support unit, the second magnetic field measurement sensor being transferred outside when the substrate is processed, and
wherein the controller controls the electromagnet unit based on data measured by the magnetic field measurement module before the substrate is processed.

12. The substrate processing apparatus as claimed in claim 11,
wherein, before the substrate is processed, the controller receives, from the first magnetic field measurement sensor and the second magnetic field measurement sensor, first magnetic field data measured by the first magnetic field measurement sensor and second magnetic field data measured by the second magnetic field measurement sensor while adjusting a magnitude of input current supplied to the coil module, and constructs a magnetic field profile derived from a correlation among the input current, the first magnetic field data, and the second magnetic field data.

13. The substrate processing apparatus as claimed in claim 12,
wherein, during substrate processing, the controller supplies the input current to the coil module, receives the first magnetic field data measured by the first magnetic field measurement sensor during substrate processing, converts the received first magnetic field data into corresponding input current in the magnetic field profile, and compares the input current supplied to the coil module with the converted input current to diagnose a state of the electromagnet unit.

14. The substrate processing apparatus as claimed in claim 13,
wherein the coil module comprises a plurality of electromagnets, and
wherein the magnetic field profile is constructed based on the first magnetic field data and the second magnetic field data measured under a combination of a plurality of input currents.

15. A substrate processing apparatus configured to perform plasma processing on a substrate, the substrate processing apparatus comprising:
a chamber having a processing space defined therein to process a substrate;
a substrate support unit configured to support and fix the substrate disposed thereon;
a gas supply unit comprising a showerhead configured to supply gas to the processing space;
an electromagnet unit configured to be located above the chamber, and to generate a magnetic field; and
a controller configured to control a substrate processing operation,
wherein the electromagnet unit comprises:
an electromagnet power supply connected to the controller and configured to supply power;
a coil module configured to receive power from the electromagnet power supply to generate a magnetic field into the processing space;
a variable core configured to be magnetized by the magnetic field generated by the coil module, thereby generating a magnetic field; and
a magnetic field measurement module comprising a first magnetic field measurement sensor located in a first region below the coil module and a second magnetic field measurement sensor located in a second region above the substrate support unit, the second magnetic field measurement sensor being transferred outside when the substrate is processed, and
wherein the controller controls the electromagnet unit based on data measured by the magnetic field measurement module before the substrate is processed.

16. The substrate processing apparatus as claimed in claim 15,
wherein the variable core is provided inside the coil module, and
wherein a magnetic field generated by the coil module and the variable core are controlled by adjusting one or more control parameters comprising a shape of the variable core, a position of the variable core, and input current supplied to the coil module.

17. The substrate processing apparatus as claimed in claim 16,
wherein, before the substrate is processed, the controller receives, from the first magnetic field measurement sensor and the second magnetic field measurement sensor, first magnetic field data measured by the first magnetic field measurement sensor and second magnetic field data measured by the second magnetic field measurement sensor while selecting one of the one or more control parameters and adjusting the selected control parameter, and constructs a magnetic field profile derived from a correlation among the selected control parameter, the first magnetic field data, and the second magnetic field data.

18. The substrate processing apparatus as claimed in claim 17,
wherein, during substrate processing, the controller receives the first magnetic field data measured by the first magnetic field measurement sensor during substrate processing, calculates a converted parameter, the converted parameter being the selected control parameter corresponding to the received first magnetic field data in the magnetic field profile, and compares the selected control parameter with the converted parameter to diagnose a state of the electromagnet unit.

19. The substrate processing apparatus as claimed in claim 16,
wherein, before the substrate is processed, the controller receives, from the first magnetic field measurement sensor and the second magnetic field measurement sensor respectively, first magnetic field data and second magnetic field data, obtained by measuring a magnetic field generated according to a combination of a plurality of adjusted control parameters, and constructs a magnetic field profile derived from a correlation among the plurality of adjusted control parameters, the first magnetic field data, and the second magnetic field data.

20. The substrate processing apparatus as claimed in claim 19,
wherein, during substrate processing, the controller receives the first magnetic field data measured by the first magnetic field measurement sensor during substrate processing, converts the received first magnetic field data into converted parameters, the converted parameters being the plurality of control parameters corresponding to the received first magnetic field data in the magnetic field profile, and compares the actually set control parameters with the converted parameters to diagnose a state of the electromagnet unit.
